(19) United States
(12) Patent Application Publication
(10) Pub. No.: US 2023/0082105 A1
(43) Pub. Date: Mar. 16, 2023

(54) DISPLAY OF ROTOR AND STATOR CONCENTRICITY CHANGES

(71) Applicant: Baker Hughes Holdings LLC, Houston, TX (US)

(72) Inventors: Pabbaraju Venkata Naga Lalith Pranith, Mumbai (IN); Ketan Ghamande, Mumbai (IN); Mark Snyder, Citrus Heights, CA (US); Kausarjahan Mulla, Mumbai (IN)

(21) Appl. No.: 17/897,596

(22) Filed: Aug. 29, 2022

Related U.S. Application Data
(60) Provisional application No. 63/244,681, filed on Sep. 15, 2021.

(51) Int. Cl. H02K 11/21; H02K 11/25

(52) U.S. Cl. CPC H02K 11/21; H02K 11/25; H02K 2201/03

(57) ABSTRACT

An asset management system can be configured to receive at least a portion of a plurality of data and to determine a concentricity of at least one of the rotor or stator. The rotor or stator concentricity can be a vector including an amplitude and an angle and can characterizes a difference between a location of a predetermined center point and a location of a geometric center point of the rotor or stator, respectively. The system can also receive a concentricity vector selection including at least one of the rotor concentricity vector or the stator concentricity vector and can receive a selection of one of the correlated operating parameters. A plot format selection can be received and a graphical user interface (GUI) including a plot can be generated. The plot can include a portion of the selected concentricity vector as a function of the selected correlated operating parameter.

### CROSS-REFERENCE TO RELATED APPLICATIONS

The present application claims priority under U.S.C. § 119 to U.S. Provisional Application No. 63/244,681 entitled “Display of Rotor and Stator Concentricity Changes” filed on Sep. 15, 2021, which is hereby expressly incorporated by reference in its entirety.

### BACKGROUND

Many industries, such as hydrocarbon extraction, refining, and power generation, can rely heavily upon operation of assets (e.g., machinery), and in some instances, continuous operation of such assets. In these environments, unplanned asset shutdown and/or failure can incur severe consequences, ranging from expenses due to loss of production and/or unplanned maintenance, to potential injury to workers, amongst others. Given these risks, it can be common to monitor selected parameters of various assets during operation using an asset monitoring system. The asset monitoring system can receive and analyze measurements of selected operating parameters in order to provide an indication of the condition of a respective asset's components, as well as the asset as a whole. As a result, deviations in asset operation from normal operation can be identified and addressed to avoid asset shutdown and/or failure. Thus, asset monitoring can provide a variety of long term benefits, such as lower production costs, reduced equipment down time, improved reliability, and enhanced safety.

### SUMMARY

Electromotive devices, such as electrical generators and electrical motors, are a class of machines that can be monitored by an asset monitoring system. In particular, these machines include a stationary component, referred to as a stator, and a rotating component, referred to as a rotor, positioned within the stator. In electrical generators, the rotor generates a magnetic field and, when rotated, induces an electrical current within windings mounted to the stator. Conversely, in electrical motors, the windings mounted to the stator generate magnetic fields that apply a magnetic force to the rotor, causing it to rotate.

In general, a diameter of the stator is greater than an outer diameter of the rotor. This provides a circumferential clearance (e.g., air gap) between the rotor and the stator. Furthermore, the rotor is designed to rotate about an axis that is positioned approximately at the center point of the stator. Thus, in theory, contact between the rotor and stator can be inhibited. However, in operation, the position of the stator and/or the axis of rotation of the rotor can move due to one or more factors (e.g., temperature gradients resulting in differential thermal expansion/contraction, loosening of fasteners, fatigue cracking, etc.) As the rotor rotates at high speed during operation, should the rotor and stator come into contact with one another, the rotor and stator can be damaged, requiring costly repair and machine down-time. In view of the consequences of contact between the rotor and stator, it can be desirable for asset monitoring systems to measure the air gap in order to identify when the distance between the rotor and stator falls below a predetermined tolerance level. As an example, the air gap measurements at the discrete angular positions of the air gap sensors can be used to infer the air gap at other annular positions and construct shape plots of the rotor and stator.

Concentricity is a parameter characterizing the deviation or offset between an ideal center point (e.g., reference center point) and an actual geometric center point (e.g., “best center”) of a component, and can be determined for both the rotor and stator from the air gap measurements. Stator concentricity characterizes the offset between the ideal center point and the geometric center point of the stator, while rotor concentricity characterizes the offset between the ideal center point and the geometric center point of the rotor. It can be desirable to measure concentricity, as it can quantify changes or deterioration of the rotor and/or stator condition, which is not readily evident from visual evaluation of rotor and/or stator shape plots provided by air gap measurements themselves.

However, existing asset monitoring systems can be limited in their ability to display concentricity changes. Notably, air gap data can be typically presented in the form of a plot illustrating the actual rotor and stator position as compared to an ideal position. To the extent that concentricity information (e.g., amplitude and/or angle) is present, this information is further listed in tabular form along with the plot of rotor and stator position.

It can be appreciated, however, that such presentations represent a single point in time. Thus, in order to identify changes occurring over time, an operator can be required to page through multiple air gap plots and review corresponding tabular concentricity information. This is cumbersome, inefficient, and not conducive to comprehensive recognition of concentricity changes occurring over time. Furthermore, it can be difficult to determine correlations between the concentricity changes with other operating parameters of the machine, such as rotation speed, or state changes of the machine (e.g., transient states [startup/shutdown events], steady-state, etc.)

Accordingly, embodiments of the present disclosure provide approaches for improved visualization of rotor and stator concentricity by asset monitoring systems. As discussed in detail below, rotor and stator concentricity can be derived from air gap measurements as vectors having an amplitude and angle. These concentricity vectors can be well suited for presentation in various types of plots, such as polar plots, Bode plots, XvsY plots, and amplitude and phase versus time (APHT) plots. Notably, the concentricity amplitude and angle can be presented together or separately, depending upon the type of plot and further correlated with one or more desired parameters (e.g., time, operating parameters of the machine, machine state, etc.) This manner of presentation more readily lends itself for comprehension of changes in concentricity amplitude and angle with the correlated parameters, as compared to the above-discussed representations provided by existing asset monitoring systems.

In an embodiment, an asset management system is provided and includes a memory and an analyzer. The memory can be configured to maintain a plurality of data. The plurality of data can include measurements characterizing an air gap between at least one of a rotor or a stator of a machine correlated with one or more operating parameters of the machine. The analyzer can include one or more processors in communication with the memory. The analyzer can be configured to perform a variety of operations. The operations can include receiving at least a portion of the plurality of the data from the memory. The operations can further include determining, based upon the received data, a concentricity of at least one of the rotor or stator. The rotor or stator concentricity can be a vector including an amplitude and an angle and that characterizes a difference between a location of a predetermined center point and a location of a geometric center point of the rotor or stator, respectively. The operations can also include receiving a concentricity vector selection including at least one of the rotor concentricity vector or the stator concentricity vector. The operations can additionally include receiving a selection of one of the correlated operating parameters. The operations can also include receiving a selection of a plot format. The operations can further include generating a graphical user interface (GUI) including a plot in the format of the selected plot type. The plot can include at least a portion of the selected concentricity vector as a function of the selected correlated operating parameter. The operations can also include outputting the generated GUI.

In another embodiment, the plot can be a polar plot.

In another embodiment, the plot can be a Bode-like plot. As an example, the Bode-like plot can include first and second Cartesian plots. The first Cartesian plot can include an amplitude of the selected concentricity vector and the selected correlated operating parameter. The second Cartesian plot can include the angle of the selected concentricity vector and the selected correlated operating parameter. The axis of the selected correlated operating parameter is common to the first and second Cartesian plots.

In another embodiment, plot is an amplitude and phase versus time (APHT) plot. The APHT plot can be similar to the Bode-like plot, with the operating parameter being time.

In another embodiment, the plot is an XvsY plot of amplitude of the selected concentricity vector and the selected correlated operating parameter.

In another embodiment, the plot does not combine the concentricity vector with a profile or shape of the rotor or stator.

In another embodiment, the one or more operating parameters can include at least one of rotor speed, rotor temperature, stator temperature, a machine state, a machine output, or hydraulic head.

In another embodiment, the analyzer can be further configured to update the GUI and output the updated GUI in response to receipt of new data.

In another embodiment, the plot further includes an acceptance region overlaid upon the portion of the selected concentricity vector within the plot. The acceptance region can include one or more threshold values corresponding to at least one of concentricity amplitude, or concentricity angle for the rotor or stator.

In another embodiment, the analyzer can be further configured to receive an alarm type corresponding to respective threshold values, compare each threshold value to the corresponding determined concentricity amplitude or concentricity angle, generate a notification based upon the alarm type when a threshold value is crossed by its corresponding determined concentricity amplitude or concentricity angle, and output the notification (e.g., to the user computing device 110 for annunciation).

In another embodiment, the generated GUI can include both the amplitude and the angle of the selected concentricity vector.

In another embodiment, the machine is an electrical generator.

In an embodiment, a method is provided. The method can include receiving, by an analyzer including one or more processors, a plurality of data including measurements characterizing an air gap between at least one of a rotor or a stator of a machine correlated with one or more operating parameters of the machine. The method can also include determining, by the analyzer based upon the received data, a concentricity of at least one of the rotor or stator. The rotor or stator concentricity can be a vector, including an amplitude and an angle, that characterizes a difference between a location of a predetermined center point and a location of a geometric center point of the rotor or stator, respectively. The method can additionally include receiving, by the analyzer, a concentricity vector selection including at least one of the rotor concentricity vector or the stator concentricity vector. The method can further include receiving, by the analyzer, a selection of one of the correlated operating parameters and a selection of a plot format. The method can also include generating, by the analyzer, a graphical user interface (GUI) including a plot in the format of the selected plot type. The plot can include at least a portion of the selected concentricity vector as a function of the selected correlated operating parameter. The method can further include outputting, by the analyzer, the generated GUI.

In another embodiment, the plot is a polar plot.

In another embodiment, the plot can be a Bode-like plot. As an example, the Bode-like plot can include first and second Cartesian plots. The first Cartesian plot can include an amplitude of the selected concentricity vector and the selected correlated operating parameter. The second Cartesian plot can include the angle of the selected concentricity vector and the selected correlated operating parameter. The axis of the selected correlated operating parameter is common to the first and second Cartesian plots.

In another embodiment, plot is an amplitude and phase versus time (APHT) plot.

In another embodiment, the plot is an XvsY plot of amplitude of the selected concentricity vector and the selected correlated operating parameter.

In another embodiment, the plot does not combine the concentricity vector with a profile or shape of the rotor or stator.

In another embodiment, the one or more operating parameters can include at least one of rotor speed, rotor temperature, stator temperature, a machine state, a machine output, or hydraulic head.

In another embodiment, the method can further include, by the analyzer, updating the GUI and outputting the updated GUI in response to receipt of new data.

In another embodiment, the plot further includes an acceptance region overlaid upon the portion of the selected concentricity vector within the plot. The acceptance region can include one or more threshold values corresponding to at least one of concentricity amplitude, or concentricity angle for the rotor or stator.

In another embodiment, the method can also include, by the analyzer, receiving an alarm type corresponding to respective threshold values, comparing each threshold value to the corresponding determined concentricity amplitude or concentricity angle, generating a notification based upon the alarm type when a threshold value is crossed by its corresponding determined concentricity amplitude or concentricity angle, and outputting the notification (e.g., to the user computing device 110 for annunciation).

In another embodiment, the generated GUI can include both the amplitude and the angle of the selected concentricity vector.

In another embodiment, the machine is an electrical generator.

### DESCRIPTION OF DRAWINGS

These and other features will be more readily understood from the following detailed description taken in conjunction with the accompanying drawings, in which:

FIG. 1 is a diagram illustrating one exemplary embodiment of an operating environment including an asset and an asset monitoring system configured to monitor a concentricity of a rotor and stator of the asset;

FIG. 2 is a schematic diagram illustrating a cross-sectional view of one exemplary embodiment of a rotor and a stator and a plurality of air gap sensors configured to measure an air gap G between the rotor and the stator;

FIG. 3A is a schematic diagram illustrating the rotor and stator and corresponding geometric center points overlapping an ideal center point;

FIG. 3B is a schematic diagram illustrating the rotor and stator and corresponding geometric center points where the geometric center point of the rotor deviates from the ideal center;

FIG. 3C is a schematic diagram illustrating the stator and corresponding stator geometric center point that deviates from the ideal center point;

FIG. 4 is a schematic representation of a graphical user interface (GUI) generated by an existing asset monitoring system illustrating rotor and stator profiles;

FIG. 5A is a schematic representation of an exemplary embodiment of a GUI of the present disclosure illustrating presentation of a concentricity vector in a polar plot;

FIG. 5B illustrates the GUI of FIG. 5B with further display of a cursor, cursor-over data, and additional tabular data;

FIG. 6 is a schematic representation of an exemplary embodiment of a GUI of the present disclosure illustrating presentation of a concentricity vector in a Bode-like plot;

FIG. 7 is a schematic representation of an exemplary embodiment of a GUI of the present disclosure illustrating presentation of a concentricity vector in an amplitude and phase versus time (APHT) plot;

FIG. 8 is a schematic representation of an exemplary embodiment of a GUI of the present disclosure illustrating presentation of one (e.g., amplitude) of the two components (the other being angle) of a concentricity vector in an XvsY plot;

FIG. 9 is a schematic representation of an exemplary embodiment of a GUI of the present disclosure illustrating presentation of the polar plot FIG. 5 side-by-side with the (APHT) plot of FIG. 7;

FIG. 10 is a flow diagram illustrating one exemplary embodiment of a method for generating the GUI of FIGS. 4-8.

It is noted that the drawings are not necessarily to scale. The drawings are intended to depict only typical aspects of the subject matter disclosed herein, and therefore should not be considered as limiting the scope of the disclosure.

### DETAILED DESCRIPTION

Electrical generators, electrical motors, and turbines are machines that include stationary components (stators) and rotating components (rotors), amongst others. These components work in combination to generate electricity in the context of electrical generators or convert electrical current into movement (rotor rotation) in the context of electrical motors. In order to perform these functions, the stator has a ring or cylindrical shape and the rotor is positioned within the stator. While the size and relative position of the rotor and stator are designed to prevent contact when the rotor rotates during operation, the rotor and/or the stator can undesirably shift position. Thus, it can be desirable to monitor changes in the geometric center point of the rotor and stator as compared to an ideal center point, referred to as concentricity. However, existing monitoring systems can present concentricity information as columns of data, which can be difficult to use in comprehending concentricity changes. Accordingly, approaches for improved visualization of rotor and stator concentricity by asset monitoring systems are provided. As discussed in detail below, rotor and stator concentricity can be represented as vectors having an amplitude and angle. These concentricity vectors can be well suited for presentation in various types of plots, where the concentricity amplitude and angle are presented together in a vector representation or as separate components. These plots can further correlate the concentricity vector or concentricity components with one or more desired parameters (e.g., time, operating parameters of the machine, machine state, etc.) This manner of presentation more readily lends itself for comprehension of changes in concentricity amplitude and angle with the correlated parameters, as compared to representations provided by existing asset monitoring systems.

Embodiments of systems and corresponding methods for visualization of concentricity of rotors and stators is discussed herein. However, embodiments of the disclosure can be employed to for visualization of concentricity of other components without limit.

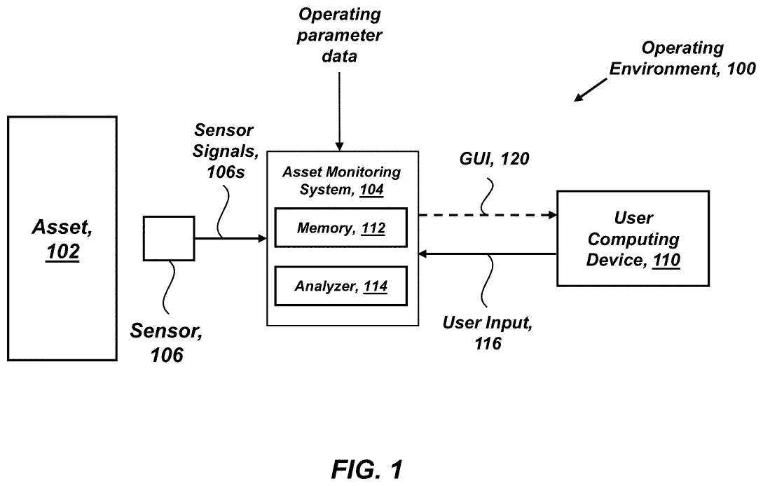

FIG. 1 is a schematic diagram illustrating one exemplary embodiment of an operating environment 100 including an asset 102 and an asset monitoring system 104. Embodiments of the asset 102 can include any machine that includes a rotor and a stator. Examples can include, but are not limited to, electrical generators and electric motors. As discussed above, and in greater detail below, the asset monitoring system 104 can be configured to measure concentricity of the rotor and stator.

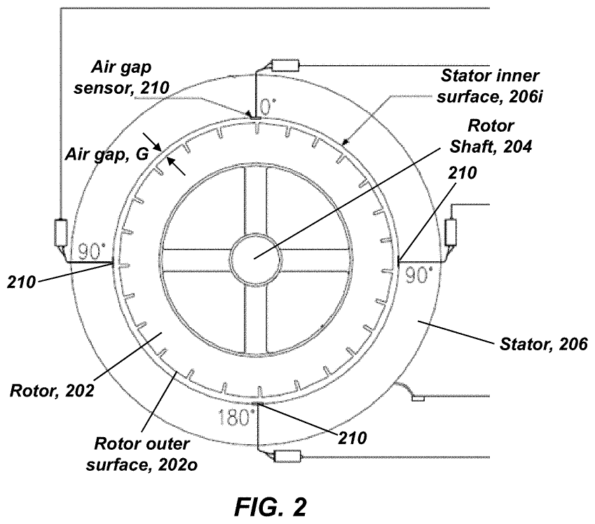

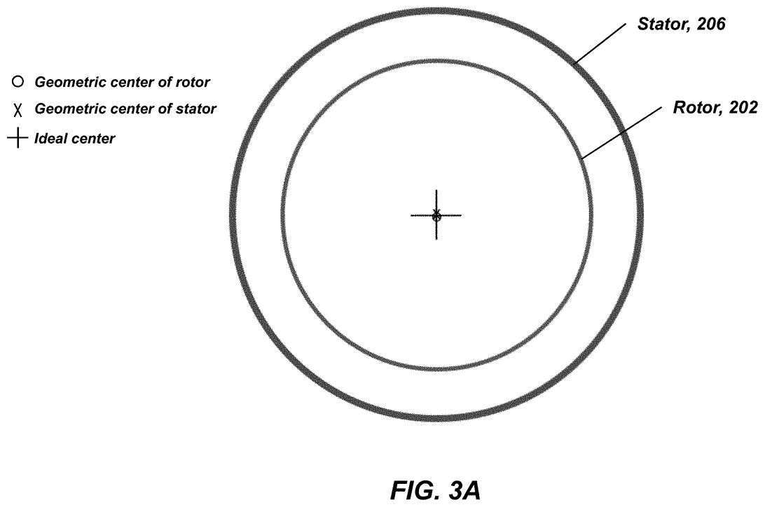

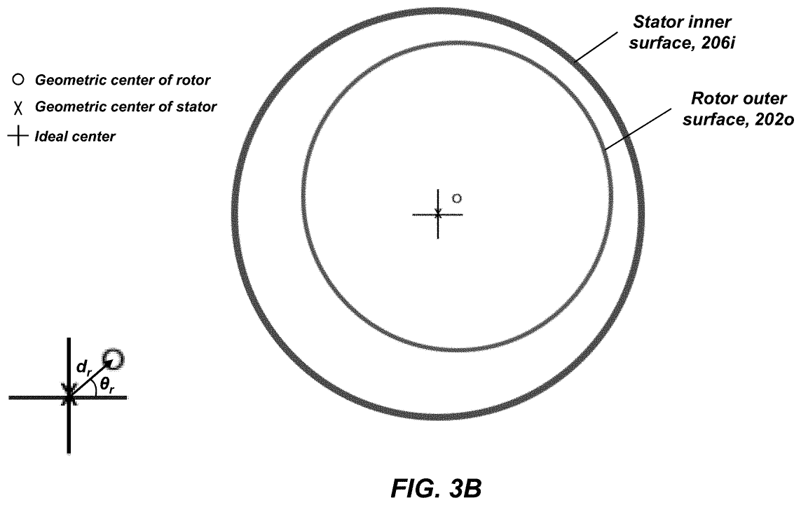

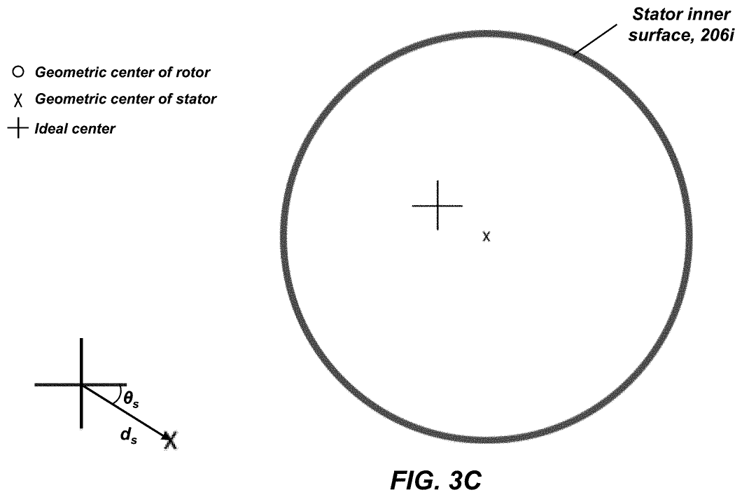

To better understand embodiments of the disclosure, various aspects of the rotor, stator, one or more sensors 106, and concentricity are discussed below in regards to FIGS. 2 and 3A-3C. As shown in FIG. 2, the rotor 202 is in the form of a generally cylindrical hub mounted to a rotor shaft 204, and the stator 206 is generally cylindrical. The rotor 202 is positioned with respect to the stator 206 such that an outer circumferential surface 202o of the rotor 202 faces an inner circumferential surface 206i of the stator 206. The outer diameter of the rotor 202 is less than the inner diameter of the stator 206 to provide an air gap G therebetween.

In order to measure concentricity, the sensors 106 are in the form of one or more air gap sensors 210. A single air gap sensor 210 may be employed for determining rotor concentricity, while two or more air gap sensors 210 may be employed for determining stator concentricity. As shown in FIG. 2, a plurality of the air gap sensors 210 are mounted to the inner circumferential surface 206i of the stator 206 at different locations. In certain embodiments, the air gap sensors can be approximately equidistant from one another. As an example when four air gap sensors are employed, they can be separated by approximately 90°. Each of the air gap sensors 210 can acquire data characterizing the air gap G at its location. These measurements can be transmitted to the asset monitoring system 104 in the form of respective sensor signals 106s. The asset monitoring system 104 in turn can determine concentricity of the rotor and stator based upon the received air gap data.

The discussion will now turn to FIGS. 3A-3C for a brief overview of concentricity. In general, a geometric center point or centroid can be defined for each of the rotor 202 and stator 206 as the arithmetic mean of all the points of each, respectively. Thus, in the case where the rotor 202 and the stator 206 possess a circular cross-section, the center point of each is the point equidistant from the points on their edges. The geometric center point of the rotor 202 is illustrated with a circle symbol and the geometric center point of the stator 206 is illustrated with an X symbol.

Concentricity of a component can be defined as an offset between a predetermined reference center point (e.g., an ideal center point) and the geometric center point of that component. Thus, the concentricity of the rotor 202 is given by the offset between the rotor geometric center point and the ideal center point, while the concentricity of the stator 206 is given by the offset between the stator geometric center point and the ideal center point. For illustration, the ideal center point is shown as a + (cross) symbol.

In FIG. 3A, the rotor geometric center point, the stator geometric center point, and the ideal center point are coincident. Thus, the rotor concentricity and stator concentricity deviations (e.g., offsets) are zero.

In FIG. 3B, the position of the rotor 202 is illustrated as being shifted with respect to the ideal center point. Taking the ideal center point to be the origin, the rotor concentricity deviation in this case is given by a vector extending from the ideal center point to the geometric center point of the rotor 202. The inset of FIG. 3B presents a magnified view of the ideal center point and the geometric center point of the rotor 202. It can be observed that the rotor concentricity deviation vector is characterized by an angle dᵣ and angle θᵣ.

In FIG. 3C, the position of the stator 206 has shifted with respect to the ideal center point. The stator concentricity in this case is given by a vector extending from the ideal center point to the geometric center point of the stator 206. The inset of FIG. 3C presents a magnified view of the ideal center point and the geometric center point of the stator 206. It can be observed that the stator concentricity deviation vector is characterized by an angle dₛ and angle θₛ.

With further reference to FIG. 1, the asset monitoring system 104 can be configured to determine rotor and stator concentricity vector values based upon the air gap measurements acquired by the air gap sensors 210. As shown, the asset monitoring system 104 includes a memory 112 and an analyzer 114 including one or more processors. The memory can be configured to receive sensor signals 106s from the sensors 106 (e.g., air gap sensors 210) representing the respective air gap measurement data. The analyzer 114 can receive the air gap measurement data from the memory 112 for determination of the rotor and stator concentricity. In an embodiment, the concentricity can be determined from the air gap measurement data by methodology based on that discussed in CEATI International Report Number T122700 0381, “CPF: Hydroelectric Turbine-Generator Units Guide for Erection Tolerances and Shaft System Alignment,” May 2015 (Parts I-VI), the entirety of each of which is incorporated by reference.

In certain embodiments, the air gap measurement data can be transmitted from the memory 112 to the analyzer 114 immediately upon receipt for analysis. In other embodiments, the air gap measurement data can be stored by the memory 112 and transmitted to the analyzer 114 at a later time for analysis. The former represents the ability to perform analysis on data acquired in real time, while the latter represents the ability to perform analysis on historical data. It can be appreciated that further embodiments of the asset monitoring system can analyze real-time and historical air gap measurement data substantially concurrently. Thus, an operator can recognize and quantify instantaneous concentricity changes by review of real-time concentricity, as well as trends over time by comparing historical concentricity.

In further embodiments, the asset monitoring system 104 can also correlate the determined rotor and stator concentricity with one or more operating parameters of the machine containing the rotor 202 and stator 206. In certain embodiments, the one or more operating parameters can be received from other sensors, from the memory 112, from operator input, or other sources as necessary.

Examples of the one or more operating parameters can include, but are not limited to, time, rotor speed, output of the machine (e.g., power output in the context of an electrical generator), hydraulic head (e.g., pressure drop) through the turbine, rotor or stator temperature. In further embodiments, the one or more operating parameters can be a state of the machine. Examples of machine states can include transient states (e.g., run-up to full speed, field excitation, breaker close, load changes, coast-down to full stop, transition from generating to pumping and vice-versa) and steady state (e.g., full load thermally stable, stable load operations, synchronous condenser operation). It may be understood that this list of operating parameters is not exhaustive and that others may be employed without limit.

Following determination of the rotor and stator concentricity vectors, the analyzer 114 can generate one or more graphical user interfaces (GUI) for display of at least a portion of the determined concentricity vectors. In certain embodiments, the content of the GUI can be specified by an operator. Thus, the analyzer 114 can be configured to receive one or more operator selections via the user computing device 110. Examples of the selections can include one or more of a concentricity vector selection including at least one of the rotor or stator concentricity vector, a plot format, and at least one of the correlated operating parameters.

In certain embodiments, the plot formats can include, but are not limited to, polar plots, Bode plots, amplitude and phase versus time (APHT) plots, and XvsY plots. Each is discussed in greater detail below.

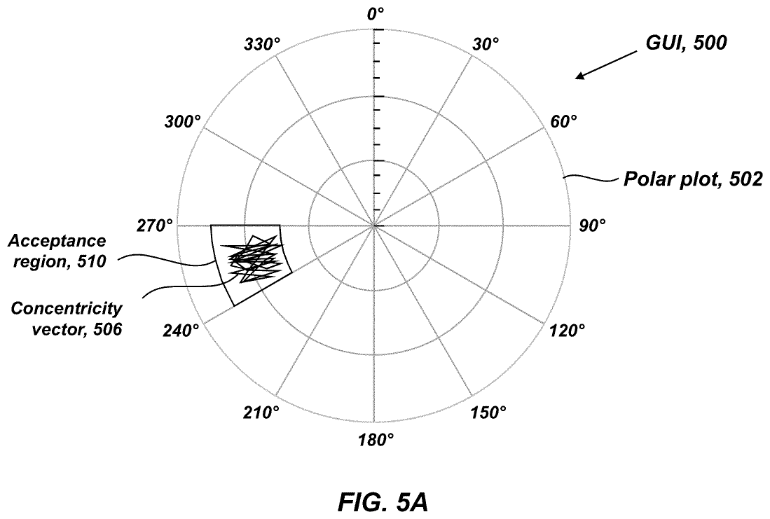

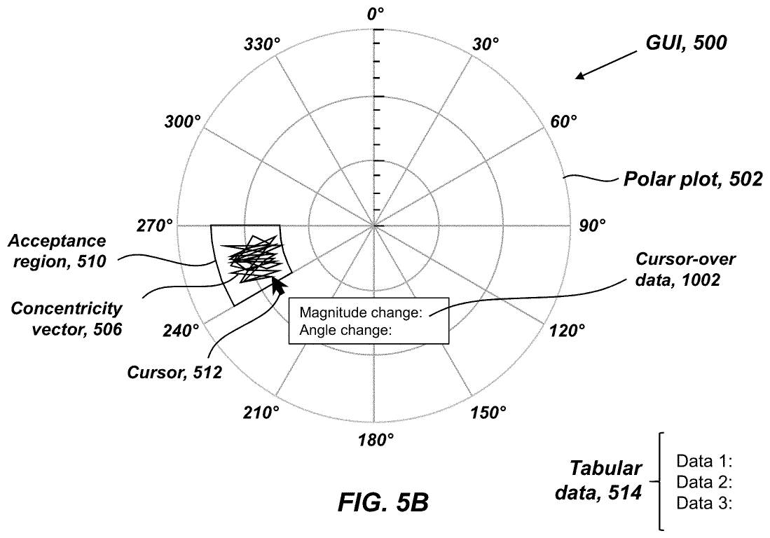

FIG. 5A illustrates one exemplary embodiment of a polar plot. As shown, graduation lines and corresponding radial and angular scale markings for concentricity amplitude and angle are provided. Any appropriate units for the angle can be adopted. Examples can include, but are not limited to, absolute (raw) values, absolute (raw) values as a percentage of the measured average air gap, etc.

In the context of a polar plot, the amplitude and angle of the selected concentricity vector are plotted together. If the operator chooses to display the rotor and stator concentricity vectors together as a function of the selected operating parameter, colors, symbols, patterns, or other visual characteristics can be used to distinguish between these concentricity vectors. Similarly, should the operator wish to display a selected concentricity vector for different machine states, the concentricity vectors can also be displayed with visual characteristics that distinguish between these concentricity vectors.

Further illustrated in FIG. 5A is an acceptance region 510 superimposed or overlaid upon the displayed concentricity vector(s). The acceptance region 510 defines upper and lower bounds for either one or both of amplitude and angle of concentricity vectors. The acceptance region 510 can be defined for the rotor concentricity and/or stator concentricity. The acceptance region 510 can be received by the analyzer for display (e.g., retrieved from the memory 112, received from operator input via the user computing device 110, etc.) In an embodiment, the acceptance region can be determined by commonly accepted industry conventions, standards organization, regulatory authorities, etc. In other embodiments, the acceptance region can be provided in accordance with guidelines established by the operator.

Non-limiting embodiments of recommended maximum offsets for rotor and stator concentricity that can be employed for the acceptance region are listed below and are incorporated by reference in their entirety.
1) CEATI International, (May 1989), part II—Vertical Shaft units with Francis Turbines or Reversible Pump Turbines, Hydroelectric Turbine-Generator Units Guide for Erection Tolerances and Shaft System Alignment, Tables 7A-8A (including the 2015 update).
2) CEATI International, (May 1988), part IV—Maintenance of Vertical Shaft Units (All types of turbines or pump-turbines), Limit for key parameters, Hydroelectric Turbine-Generator Units Guide for Erection Tolerances and Shaft System Alignment, pp. 54, 59-61 (including the 2015 update).

It can be appreciated that the GUI 500 can further include multiple acceptance regions 510. As an example, a first acceptance region can represent a warning that a concentricity limit is being approached, while a second acceptance region can represent an alarm that the concentricity limit has been crossed.

As an example, the analyzer 114 can compare the selected concentricity represented within the GUI 500 with the limits defined by one or more acceptance region 510. Under circumstances where the analyzer 114 determines that the selected concentricity has crossed the limits defined by the acceptance region 510, the analyzer 114 can generate a corresponding notification (e.g., warning, alarm, etc.) and transmit the notification to the user computing device 110. Upon receipt, the user computing device 110 can annunciate the notification.

Embodiments of the annunciation can adopt a variety of forms, alone or in combination. In one aspect, annunciation can be an audio and/or visual cue intended to attract the attention of an operator. In another aspect, the annunciation can be written to an event log for further troubleshooting and analysis.

The GUI can be further configured to display changes in the concentricity vector 506 (e.g., angle and/or angle) for discrete transients or defined periods of time. This information can be displayed in response to movement of a cursor 512 over the concentricity vector 506. In other embodiments, tabular data pertaining to one or more concentricity vectors 506 can be displayed for discrete transients (e.g., different operating states) or defined periods of time.

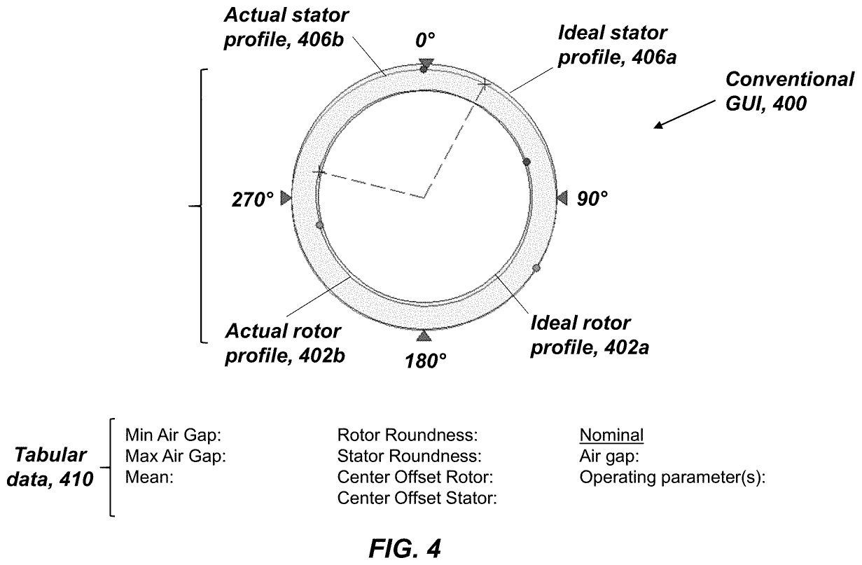

It will be appreciated that display of the concentricity vector provides significantly improved ability to comprehend changes in the concentricity vector(s) as compared to existing asset monitoring systems. An existing GUI 400 is illustrated in FIG. 4 for comparison. As shown, an ideal rotor profile 402a, actual rotor profile 402b, ideal stator profile 406a, and actual stator profile 406b are displayed. Also shown are calculated values for roundness (e.g., circularity) and offset (e.g., concentricity) for the rotor 202 and the stator 206 in tabular form. Notably, concentricity change information as a function of time, state, load or other operating parameter is not presented directly but can require inference from offset data at multiple times. However, as the illustrated GUI 400 of FIG. 4 is representative of a single point in time, an operator must page through multiple plots of this type in order to make a determination regarding concentricity changes.

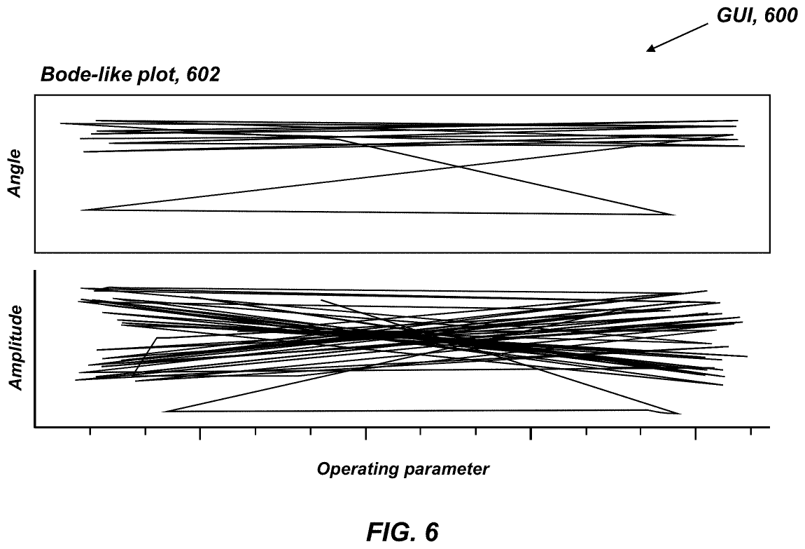

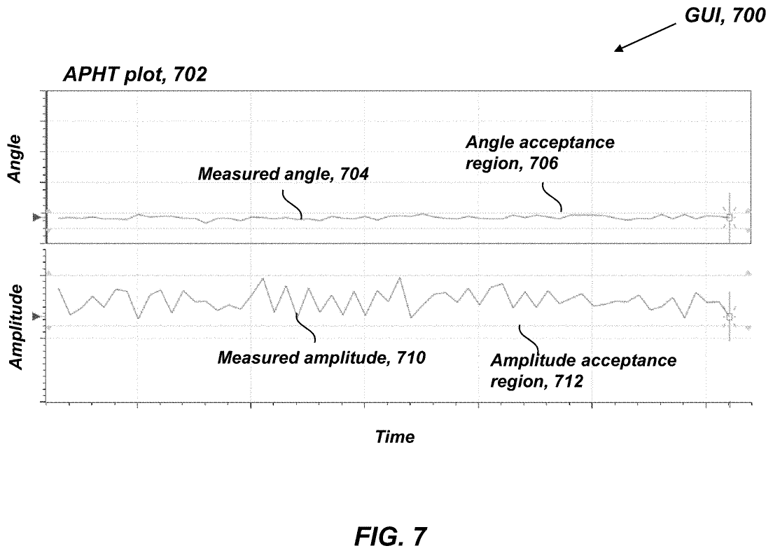

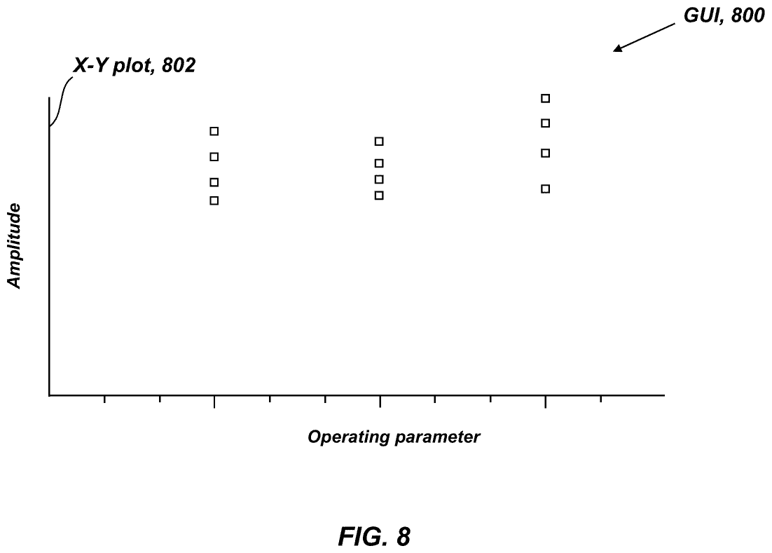

The above-discussed advantages provided by the GUI 500 in comparison with conventional presentations provided by existing asset monitoring systems also carry over to other types of plots noted above as well. An exemplary embodiment of a Bode-like plot is illustrated in FIG. 6. An exemplary embodiment of an APHT plot is illustrated in FIG. 7. An exemplary embodiment of an XvsY plot is illustrated in FIG. 8.

In general, a Bode plot is traditionally used in electrical engineering, amongst other disciplines, to plot frequency response of a system and combines a plot of the amplitude of the frequency response and a plot of the phase shift of the frequency response. FIG. 6 illustrates an exemplary embodiment of a GUI 600 including a plot that adapts this format to present respective plots of amplitude and angle of the selected concentricity vector as a function of the selected operating parameter, and is referred to herein as a Bode-like plot 602. As the Bode-like plot 602 arranges the amplitude and angle components of the concentricity vector into separate but adjacent plots that are aligned according to the selected operating parameter, it can be easier to visualize how each component behaves as a function of the selected operating parameter, including proximity to their corresponding acceptance region boundaries.

FIG. 7 illustrates a GUI 700 including of amplitude and phase versus time (APHT) plot 702. The APHT plot 702 is similar to the Bode-like plot 602 of FIG. 6, including respective plots of measured angle (phase) 704 and measured amplitude 710 of the selected concentricity vector but restricts the correlated operating parameter to time. The APHT plot can help evaluate changes over relatively long periods of steady state operation.

As further shown in FIG. 7, acceptance regions can be presented for each of the angle and amplitude of the selected concentricity vector (angle acceptance region 706 and amplitude acceptance region 712). As the APHT plot 702 is a Cartesian plot, the upper and lower bounds of acceptance regions 706, 712 are illustrated as parallel horizontal lines.

FIG. 8 illustrates a GUI 800 including an XvsY plot 802. The XvsY plot 802 includes only the amplitude of the selected concentricity vector as a function of the selected operating parameter. The XvsY plot 802 can be helpful for visualizing and characterizing correlations or dependencies between one of the components of the circularity vector and a selected operating parameter.

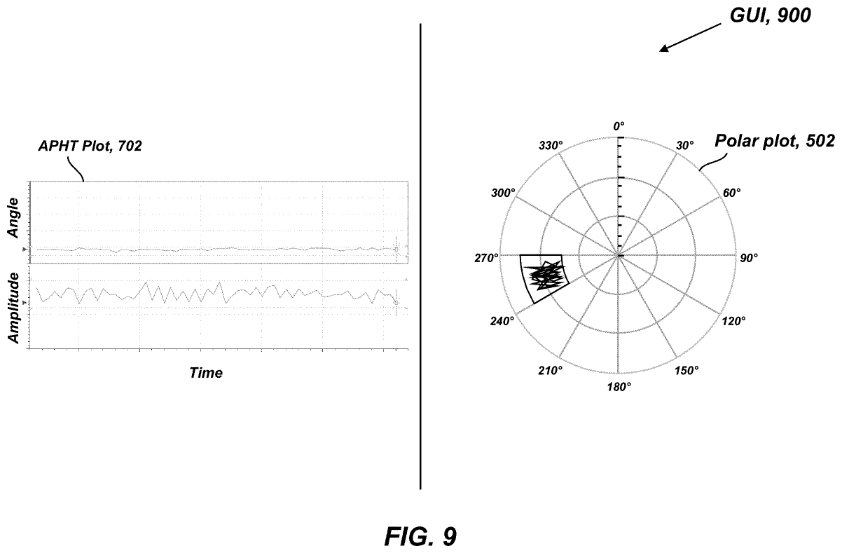

In further embodiments, as illustrated in FIG. 9, the analyzer 114 can be configured to generate a GUI 900 that presents two or more of plots. Examples of the plots can include two or more of the plots 502, 602, 702, 802, in any combination. In further embodiments, the GUI can include one or more of the plots 502, 602, 702, 802 and any other type of plot available from the asset monitoring system 104 (e.g., air gap circular profile plots, rotor shape plots, stator shape plots, etc.) For example, the GUI 900 of FIG. 9 presents the APHT plot 702 side-by-side with the polar plot 502. Visualizing the same data in two different plot types side-by-side can enhance the understanding of the measured values, especially when the cursors of both plots are synchronized to the same measurement sample, time, value of selected operating parameter, etc.

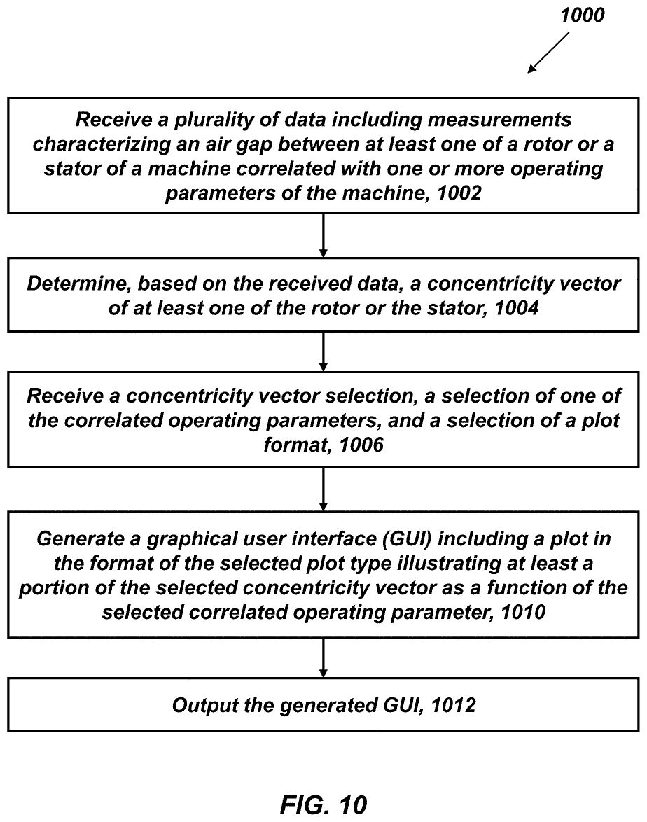

FIG. 10 is a flow diagram illustrating one exemplary embodiment of a method 1000 for generating GUIs (e.g., GUIs 500, 600, 700, 800, 900) employing the asset monitoring system 104 of FIG. 1. As shown, the method 1000 includes operations 1002-1012. However, it can be understood that alternative embodiments of the method can include greater or fewer operations and that the operations can be performed in an order different than that illustrated in FIG. 10.

In operation 1002, the analyzer 114 can receive the plurality of data including the air gap measurements. As discussed above, the air gap measurements can characterize the air gap G between at least one of the rotor 202 or the stator 206 of the machine (e.g., an electrical generator, an electrical motor, etc.) and can be correlated with one or more operating parameters of the machine. Examples of the operating parameters can include, but are not limited to, time, rotor speed, rotor temperature, stator temperature, a machine state, a machine output, or hydraulic head.

In operation 1004, the analyzer 114 can determine a concentricity of at least one of the rotor 202 or the stator 206 based on the received data. The concentricity can be a vector having an amplitude and an angle characterizing the difference between a location of a predetermined center point and a location of a geometric center point of the rotor or stator.

In operation 1006, the analyzer 114 can receive a variety of selections. The selections can include a concentricity vector selection (e.g., at least one of the rotor concentricity vector and the stator concentricity vector), a selection of one of the correlated operating parameters, and a selection of the plot format. Examples of plot formats can include polar plots, Bode-like plots, amplitude and phase versus time (APHT) plots, or XvsY plots.

In operation 1010, the analyzer 114 can generate the GUI including a plot in the format of the selected plot type and including at least a portion of the selected concentricity vector as a function of the selected correlated operating parameter.

In operation 1012, the analyzer 114 can output the GUI. As an example, the analyzer 114 can output the GUI to the user computing device 110 for display.

Exemplary technical effects of the methods, systems, and devices described herein include, by way of non-limiting example, improved graphical user interfaces (GUIs) for display of concentricity or rotors and/or stators. These GUIs can enable an operator to more easily visualize changes in concentricity amplitude and angle across transient events as well as through defined periods of operation. The GUIs can further include acceptance regions defined by predetermined standards.

Certain exemplary embodiments have been described to provide an overall understanding of the principles of the structure, function, manufacture, and use of the systems, devices, and methods disclosed herein. One or more examples of these embodiments have been illustrated in the accompanying drawings. Those skilled in the art will understand that the systems, devices, and methods specifically described herein and illustrated in the accompanying drawings are non-limiting exemplary embodiments and that the scope of the present invention is defined solely by the claims. The features illustrated or described in connection with one exemplary embodiment may be combined with the features of other embodiments. Such modifications and variations are intended to be included within the scope of the present invention. Further, in the present disclosure, like-named components of the embodiments generally have similar features, and thus within a particular embodiment each feature of each like-named component is not necessarily fully elaborated upon.

The subject matter described herein can be implemented in analog electronic circuitry, digital electronic circuitry, and/or in computer software, firmware, or hardware, including the structural means disclosed in this specification and structural equivalents thereof, or in combinations of them. The subject matter described herein can be implemented as one or more computer program products, such as one or more computer programs tangibly embodied in an information carrier (e.g., in a machine-readable storage device), or embodied in a propagated signal, for execution by, or to control the operation of, data processing apparatus (e.g., a programmable processor, a computer, or multiple computers). A computer program (also known as a program, software, software application, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub-programs, or portions of code). A computer program can be deployed to be executed on one computer or on multiple computers at one site or distributed across multiple sites and interconnected by a communication network.

The processes and logic flows described in this specification, including the method steps of the subject matter described herein, can be performed by one or more programmable processors executing one or more computer programs to perform functions of the subject matter described herein by operating on input data and generating output. The processes and logic flows can also be performed by, and apparatus of the subject matter described herein can be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processor of any kind of digital computer. Generally, a processor will receive instructions and data from a read-only memory or a random access memory or both. The essential elements of a computer are a processor for executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. Information carriers suitable for embodying computer program instructions and data include all forms of non-volatile memory, including by way of example semiconductor memory devices, (e.g., EPROM, EEPROM, and flash memory devices); magnetic disks, (e.g., internal hard disks or removable disks); magneto-optical disks; and optical disks (e.g., CD and DVD disks). The processor and the memory can be supplemented by, or incorporated in, special purpose logic circuitry.

To provide for interaction with a user, the subject matter described herein can be implemented on a computer having a display device, e.g., a CRT (cathode ray tube) or LCD (liquid crystal display) monitor, for displaying information to the user and a keyboard and a pointing device, (e.g., a mouse or a trackball), by which the user can provide input to the computer. Other kinds of devices can be used to provide for interaction with a user as well. For example, feedback provided to the user can be any form of sensory feedback, (e.g., visual feedback, auditory feedback, or tactile feedback), and input from the user can be received in any form, including acoustic, speech, or tactile input.

The techniques described herein can be implemented using one or more modules. As used herein, the term “module” refers to computing software, firmware, hardware, and/or various combinations thereof. At a minimum, however, modules are not to be interpreted as software that is not implemented on hardware, firmware, or recorded on a non-transitory processor readable recordable storage medium (i.e., modules are not software per se). Indeed “module” is to be interpreted to always include at least some physical, non-transitory hardware such as a part of a processor or computer. Two different modules can share the same physical hardware (e.g., two different modules can use the same processor and network interface). The modules described herein can be combined, integrated, separated, and/or duplicated to support various applications. Also, a function described herein as being performed at a particular module can be performed at one or more other modules and/or by one or more other devices instead of or in addition to the function performed at the particular module. Further, the modules can be implemented across multiple devices and/or other components local or remote to one another. Additionally, the modules can be moved from one device and added to another device, and/or can be included in both devices.

The subject matter described herein can be implemented in a computing system that includes a back-end component (e.g., a data server), a middleware component (e.g., an application server), or a front-end component (e.g., a client computer having a graphical user interface or a web browser through which a user can interact with an implementation of the subject matter described herein), or any combination of such back-end, middleware, and front-end components. The components of the system can be interconnected by any form or medium of digital data communication, e.g., a communication network. Examples of communication networks include a local area network (“LAN”) and a wide area network (“WAN”), e.g., the Internet.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value or other range of normal tolerance in the art (e.g., within about 2 standard deviations of the mean or within 10%, 9%, 8%, 7%, 6%, 5%, 4%, 3%, 2%, 1%, 0.5%, 0.1%, 0.05%, or 0.01% of the stated value). Here and throughout the specification and claims, range limitations may be combined and/or interchanged, such ranges are identified and include all the sub-ranges contained therein unless context or language indicates otherwise.

One skilled in the art will appreciate further features and advantages of the invention based on the above-described embodiments. Accordingly, the present application is not to be limited by what has been particularly shown and described, except as indicated by the appended claims. All publications and references cited herein are expressly incorporated by reference in their entirety.

1. An asset management system, comprising:
a memory configured to maintain a plurality of data including measurements characterizing an air gap between at least one of a rotor or a stator of a machine correlated with one or more operating parameters of the machine;
an analyzer including one or more processors in communication with the memory and configured to:
receive at least a portion of the plurality of the data from the memory;
determine, based upon the received data, a concentricity of at least one of the rotor or stator, wherein the rotor or stator concentricity is a vector, including an amplitude and an angle, that characterizes a difference between a location of a predetermined center point and a location of a geometric center point of the rotor or stator, respectively;
receive a concentricity vector selection including at least one of the rotor concentricity vector or the stator concentricity vector;
receive a selection of one of the correlated operating parameters;
receive a selection of a plot format;
generate a graphical user interface (GUI) including a plot in the format of the selected plot type, the plot including at least a portion of the selected concentricity vector as a function of the selected correlated operating parameter; and
output the generated GUI.

2. The system of claim 1, wherein the plot is a polar plot.

3. The system of claim 1, wherein the plot comprises first and second Cartesian plots, the first Cartesian plot including amplitude of the selected concentricity vector and the selected correlated operating parameter, the second Cartesian plot including angle of the selected concentricity vector and the selected correlated operating parameter, and wherein the axis of the selected correlated operating parameter is common to the first and second Cartesian plots.

4. The system of claim 3, wherein the operating parameter is time.

5. The system of claim 1, wherein the plot is an XvsY plot of amplitude of the selected concentricity vector and the selected correlated operating parameter.

6. The system of claim 1, wherein the plot does not combine the concentricity vector with a profile or shape of the rotor or stator.

7. The system of claim 1, wherein the one or more operating parameters comprise at least one of rotor speed, rotor temperature, stator temperature, a machine state, a machine output, or hydraulic head.

8. The system of claim 1, wherein the analyzer is configured to update the GUI and output the updated GUI in response to receipt of new data.

9. The system of claim 1, wherein the plot further comprises an acceptance region overlaid upon the portion of the selected concentricity vector within the plot, wherein the acceptance region comprises one or more threshold values corresponding to at least one of concentricity amplitude, or concentricity angle for the rotor or stator.

10. The system of claim 9, wherein the analyzer is further configured to:
receive an alarm type corresponding to respective threshold values;
compare each threshold value to the corresponding determined concentricity amplitude or concentricity angle;
generate a notification based upon the alarm type when a threshold value is crossed by its corresponding determined concentricity amplitude or concentricity angle; and
output the notification.

11. The system of claim 1, wherein the generated GUI includes both the amplitude and the angle of the selected concentricity vector.

12. The system of claim 1, wherein the machine is an electrical generator.

13. A method, comprising:
receiving, by an analyzer including one or more processors, a plurality of data including measurements characterizing an air gap between at least one of a rotor or a stator of a machine correlated with one or more operating parameters of the machine;
determining, by the analyzer based upon the received data, a concentricity of at least one of the rotor or stator, wherein the rotor or stator concentricity is a vector, including an amplitude and an angle, that characterizes a difference between a location of a predetermined center point and a location of a geometric center point of the rotor or stator, respectively;
receiving, by the analyzer, a concentricity vector selection including at least one of the rotor concentricity vector or the stator concentricity vector;
receiving, by the analyzer, a selection of one of the correlated operating parameters;
receiving, by the analyzer, a selection of a plot format;
generating, by the analyzer, a graphical user interface (GUI) including a plot in the format of the selected plot type, the plot including at least a portion of the selected concentricity vector as a function of the selected correlated operating parameter; and
outputting, by the analyzer, the generated GUI.

14. The method of claim 13, wherein the plot comprises first and second Cartesian plots, the first Cartesian plot including amplitude of the selected concentricity vector and the selected correlated operating parameter, the second Cartesian plot including angle of the selected concentricity vector and the selected correlated operating parameter, and wherein the axis of the selected correlated operating parameter is common to the first and second Cartesian plots.

15. The method of claim 13, wherein the plot is an XvsY plot of amplitude of the selected concentricity vector and the selected correlated operating parameter.

16. The method of claim 13, wherein the plot does not combine the concentricity vector with a profile or shape of the rotor or stator.

17. The method of claim 13, wherein the one or more operating parameters comprise at least one of rotor speed, rotor temperature, stator temperature, a machine state, a machine output, or hydraulic head.

18. The method of claim 13, wherein the plot further comprises an acceptance region overlaid upon the portion of the selected concentricity vector within the plot, wherein the acceptance region comprises one or more threshold values corresponding to at least one of concentricity amplitude, or concentricity angle for the rotor or stator.

19. The method of claim 18, wherein the analyzer is further configured to:
receive an alarm type corresponding to respective threshold values;
compare each threshold value to the corresponding determined concentricity amplitude or concentricity angle;
generate a notification based upon the alarm type when a threshold value is crossed by its corresponding determined concentricity amplitude or concentricity angle; and
output the notification.

20. The method of claim 13, wherein the generated GUI includes both the amplitude and the angle of the selected concentricity vector.
